(19) United States
(12) Patent Application Publication
(10) Pub. No.: US 2009/0238972 A1
(43) Pub. Date: Sep. 24, 2009

(54) METHODS AND APPARATUS FOR USING REDUCED PURITY SILANE TO DEPOSIT SILICON

(75) Inventors: Daniel O. Clark, Pleasanton, CA (US); Mehran Moalem, Cupertino, CA (US); Robbert M. Vermeulen, Pleasant Hill, CA (US); Yong Kee Chae, Pleasanton, CA (US); Charles Gay, Westlake Village, CA (US); John M. White, Hayward, CA (US); Robert Z. Bachrach, Burlingame, CA (US); Jay J. Jung, Sunnyvale, CA (US)

Correspondence Address: DUGAN & DUGAN, PC, 245 Saw Mill River Road, Suite 309, Hawthorne, NY, 10532, US

(73) Assignee: APPLIED MATERIALS, INC., Santa Clara, CA (US)

(21) Appl. No.: 12/410,063

(22) Filed: Mar. 24, 2009

Related U.S. Application Data
(60) Provisional application No. 61/039,101, filed on Mar. 24, 2008.
(60) Provisional application No. 61/052,164, filed on May 9, 2008.

(51) Int. Cl. C23C 16/42

(52) U.S. Cl. 427/255.28; 118/715; 118/712

(57) ABSTRACT

In one aspect, a method of forming a silicon layer on a substrate is provided, including the steps providing a substrate; and introducing hydrogen and silane into a chamber containing the substrate such that a layer of silicon is deposited on the substrate; wherein the silane is less than about 99.999% pure. Numerous other aspects are provided.

The present application claims priority to U.S. Provisional Patent Application No. 61/039,101, filed Mar. 24, 2008, and entitled “METHODS FOR USING REDUCED PURITY SILANE TO DEPOSIT AMORPHOUS AND MICROCRYSTALLINE SILICON”, (Attorney Docket No. 13326/L), which is hereby incorporated herein by reference in its entirety for all purposes.

The present application claims priority to U.S. Provisional Patent Application Ser. No. 61/052,164, filed May 9, 2008 and entitled “METHODS AND APPARATUS FOR REDUCING THE CONSUMPTION OF REAGENTS IN ELECTRONIC DEVICE MANUFACTURING PROCESSES” (Attorney Docket No. 13543), which is hereby incorporated by reference herein in its entirety and for all purposes.

### RELATED APPLICATIONS

Co-assigned U.S. patent application Ser. No. 11/565,400 filed Nov. 30, 2006, and entitled “DILUTION GAS RECIRCULATION”, (Attorney Docket No. 11402), is hereby incorporated herein by reference in its entirety for all purposes.

### FIELD OF THE INVENTION

The present invention relates generally to electronic device manufacturing and is more particularly directed to the use of reduced purity silane for depositing silicon on a substrate, and the reclaim and recycle of reagent gases which are used in electronic device manufacturing processes.

### BACKGROUND OF THE INVENTION

Some electronic device manufacturing processes may use large quantities of expensive reagents, and some of these reagents may be harmful and/or hazardous if released to the atmosphere. It is known to abate these reagents and their byproducts through the use of abatement systems which convert the reagents or their byproducts into less harmful and/or hazardous compounds. While the abatement of these reagents and their byproducts may address the issue of the harmful and/or hazardous nature of the reagents/byproducts, it does not address the fact that a significant quantity of expensive reagents may eventually be wasted when the reagents pass unused through a process chamber.

It is desirable to develop methods and apparatus which would reduce the amount of expensive reagents which are required to be produced and/or purchased for use in electronic device manufacturing processes.

### SUMMARY OF THE INVENTION

In one aspect, a method of forming a silicon layer on a substrate is provided, including the steps providing a substrate; and introducing hydrogen and silane into a chamber containing the substrate such that a layer of silicon is deposited on the substrate; wherein the silane is less than about 99.999% pure.

In another aspect, a method for forming a silicon layer on a substrate is provided, including the steps: a) introducing hydrogen and silane into a deposition chamber containing a substrate such that a layer of silicon is deposited on the substrate; b) recovering silicon from an effluent stream which exits the deposition chamber; c) using the silicon recovered in step b) to produce silane; d) using the silane produced in step c) as at least a part of the silane which is introduced into the deposition chamber in step a).

In another aspect, a method for forming a silicon layer on a substrate is provided, including the steps: a) introducing hydrogen and silane into a deposition chamber containing a substrate such that a layer of silicon is deposited on the substrate; b) recovering silane from an effluent stream which exits the deposition chamber; c) introducing the silane recovered in step b) into a gas box which is adapted to supply gases to the deposition chamber; and d) supplying an amount of make-up silane to the deposition chamber sufficient to raise the purity of the combined recovered silane and make-up silane to at least a predetermined specification.

In another aspect, an apparatus for depositing silicon on a substrate is provided, including a deposition chamber; a source of silicon connected to the chamber; a source of hydrogen connected to the chamber; and a silicon separator adapted to receive an effluent stream produced by the deposition chamber and to provide silicon species suitable for use in producing silane.

In another aspect, an apparatus for depositing silicon on a substrate is provided, including: a deposition chamber; a source of silicon connected to the chamber; a source of hydrogen connected to the chamber; a hydrogen separator adapted to receive an effluent stream produced by the deposition chamber and to produce a recycled hydrogen stream; and a gas box which is adapted to receive the recycled hydrogen stream from the hydrogen separator and to provide recycled hydrogen to the deposition chamber. Numerous other aspects are provided in accordance with these and other aspects of the invention. Other features and aspects of the present invention will become more fully apparent from the following detailed description, the appended claims and the accompanying drawings.

### BRIEF DESCRIPTION OF THE DRAWINGS

FIG. 1 is a schematic depiction of a substrate coating system of the invention adapted to reclaim and recycle hydrogen.

FIG. 1A is a schematic depiction of a substrate coating system of the invention adapted to reclaim and recycle hydrogen.

FIG. 1B is a schematic depiction of a substrate coating system of the invention adapted to reclaim and recycle hydrogen.

FIG. 1C is a schematic depiction of a substrate coating system of the invention adapted to reclaim and recycle hydrogen.

FIG. 1D is a schematic depiction of a substrate coating system of the invention adapted to reclaim and recycle hydrogen.

FIG. 2 is a schematic depiction of a substrate coating system of the invention adapted to reclaim and recycle hydrogen and silicon.

FIG. 3 is a schematic depiction of a substrate coating system of the invention adapted to reclaim and recycle hydrogen.

FIG. 4 is a schematic depiction of a substrate coating system of the invention adapted to reclaim and recycle hydrogen and silicon.

FIG. 5 is a schematic depiction of a substrate coating system of the invention adapted to reclaim and recycle hydrogen and silicon.

FIG. 6 is a flowchart depicting a method for coating silicon onto a substrate using silicon recovered from an effluent stream.

FIG. 7 is a flowchart depicting a method for coating silicon onto a substrate using recovered silicon and recovered hydrogen.

FIG. 8 is a flowchart depicting a method for coating silicon onto a substrate using recovered silicon and recovered hydrogen.

### DETAILED DESCRIPTION

Electronic device manufacturing processes may use large amounts of reagents, such as silane and hydrogen. A substantial portion of these reagents, which may be expensive and/or scarce, may pass from a process chamber unused, to be treated as waste.

In a typical substrate coating process prior to the invention, such as, for example, a solar panel coating process, silane and hydrogen gases may be introduced into a substrate coating chamber under substrate coating process conditions. Amorphous and microcrystalline silicon may be deposited in a chemical vapor deposition chamber, or other suitable process chamber, using silane and hydrogen as reagents. Similarly, silane and hydrogen may be used to form a single crystal silicon coating on an insulator.

The silane typically used in such deposition processes may be at least 99.99999% pure, or “seven nines pure,” and such silane may be expensive and/or scarce. A problem associated with silane deposition processes, is that a significant amount of the hydrogen and silane which is introduced into the substrate coating chamber may pass through the substrate coating chamber unused. For example, In typical solar panel silicon deposition processes, less than about 20% of the silane introduced into the coating chamber may become consumed while coating silicon on one side of the glass. That translates into more than about 80% of the reagent silane being exhausted unused, e.g., wasted, from the chamber. Prior to the present invention unused hydrogen and silane have typically been treated as harmful and/or dangerous effluent and abated in a suitable abatement unit. Such an abatement unit may be a thermal abatement unit in which the effluent is heated and mixed with an oxidant to oxidize the effluent.

In light of the fact that silane may be expensive and more difficult to obtain in the future, and in light of the fact that some electronic device manufacturing fabrication plants may be located in relatively remote locations where it is difficult or expensive to truck or pipe in reagents, it would be desirable to avoid wasting these reagents, and/or to reduce the purity requirements of these reagents, so that only lesser amounts of perhaps cheaper reagents may need to be obtained from suppliers and lesser amounts may need to be treated as waste.

In one aspect, the present invention provides methods and apparatus for reclaiming hydrogen and/or silane for reuse as reagents in a substrate coating process. This may be accomplished by taking an effluent stream of unused reagents from the substrate coating chamber and scrubbing it to remove impurities. The scrubbed unused reagent stream may then be passed through a cold trap or a refrigerated chiller, for example, to further purify the unused reagent stream. Next, the unused reagent stream may be passed through a dryer to remove water which may be present in the unused reagent stream. The unused reagents may then be separated from each other and passed back to a gas box from which they may be supplied to the substrate coating chamber as a reagent. The unused reagents may be simply passed back to the gas box without being separated, as well. In an alternative aspect, the unused reagents may be introduced into a buffer tank rather than directly to the gas box.

In another aspect, the present invention provides methods and apparatus for reclaiming hydrogen for reuse as a reagent in a substrate coating process, and for reclaiming silicon for use in the manufacture of silane, which silane may then be used as a reagent in the substrate coating process. This may be accomplished by taking a stream of unused reagent from the substrate coating chamber and passing it through a silicon filter to remove silicon, silane, di-silane, tri-silane, and poly-silane from the unused reagent stream. In addition, to remove any dopants which may be present in the unused reagent stream, the unused reagent stream may be passed through a dopant filter, or an adsorption or absorption separation matrix. The unused reagent stream that has been passed through the filters may then consist primarily of hydrogen which may be passed to a gas box from which it may be sent to the substrate coating chamber for reuse.

In another aspect of the invention, methods and apparatus are provided to recycle hydrogen and silane for reuse in a process chamber. In this embodiment, at least a portion of the gasses which exit the substrate coating chamber as effluent may be diverted through a valve into a reclaim/recycle sub-system to form a recycle stream. The recycle stream may contain hydrogen and silane, in addition to possibly heavier impurities, such as dopant materials.

In another aspect of the invention, the diversion of the recycle stream from the effluent stream may be accomplished at different locations. Thus, in some aspects, the recycle stream may be diverted from the effluent stream between the outlet of the substrate coating chamber and the inlet of the blower-pump package. In other aspects, the recycle stream may be diverted from the effluent stream after a blower of the blower-pump package, but before a mechanical pump stack thereof. In yet other aspects, the recycle stream may be diverted from the effluent stream from a location between stages of the mechanical pump stack, before nitrogen is added to the effluent stream.

In some aspects of the invention where the recycle stream is diverted from the effluent stream before the blower-pump package, the reclaim/recycle sub-system may have one or more recycle blowers. These recycle blowers may be low pressure water cooled blowers, although non-water cooled blowers may be used. The recycle blowers may be lower tolerance blowers and may provide the benefits of less energy being needed to run the blowers and less heat being transferred to the gasses being moved by the blowers. In aspects wherein more than one recycle blower is used, the blowers may be staged so as to increase the pressure of the recycle stream while imparting a reduced amount of heat to the recycle stream. Any blowers or pumps which can increase the pressure of the recycle stream to, for example, between about 10 to about 40 p.s.i., about 20 to about 30 p.s.i. or about 10 to about 20 p.s.i., may be used. Other higher and lower pressures may be used. The recycle blowers may reduce or eliminate the transmission of any back pressure waves from the recycle stream to the effluent stream and the process chamber. In other aspects, where the recycle stream is diverted from the effluent stream after the blower, the recycle blowers may not be necessary. After the recycle stream has been diverted from the effluent stream, impurities in the recycle stream may be separated from the hydrogen and silane with a separation unit. In some aspects, the silane may also be separated from the hydrogen with a separation unit.

In some aspects of the invention, the recycle stream may be diverted from the effluent stream after the effluent stream has passed through the blower pump package. The gases, including unused hydrogen and silane, which exit a substrate coating process chamber may be at very low pressure, on the order of between about 1 and about 20 Torr. For this reason, a blower-pump package, which may consist of a blower and/or a mechanical pump stack, may be used to evacuate the gases from the substrate coating chamber, and pressurize them to a pressure at which the gases may be abated in an abatement unit. In a typical system, inert gas, e.g., nitrogen, may be added to the gases in order to increase the ease and efficiency of pumping hydrogen, which may be challenging to pump at low pressures. The nitrogen may be added before the mechanical pump or between stages of the mechanical pump. In such a case, nitrogen may also be recovered from the effluent stream and reused to assist pumping hydrogen.

In another aspect, the present invention may relieve the lack of silane supply by providing methods of manufacturing solar panels using silane which is less than seven nines pure. At least one specification of a less pure silane is silane which contains di- and/or tri-silane, in addition to silane. For example, a lower grade silane reagent of the invention may include up to about 1 wt. % di- and/or tri-silane, between about 1 wt. % and about 2 wt. % di- and/or tri-silane or up to about 5 wt. % di- and/or tri-silane. Additionally, the same or another lower grade silane reagent of the present invention may contain up to about 0.1 wt % dichlorosilane and/or trichlorosilane. By allowing the silane reagent to contain impurities, the purification process may be foreshortened and made less costly.

One approach to source silane may be to capture silane at an earlier purification step to increase production yield and reduce cost. In the production of silane, the silane may be passed through a series of distillation columns, and the silane exiting each succeeding distillation column may be more pure than the silane which exited the preceding column. An acceptable purity of silane may be taken from an earlier one of these so-called fractional cuts of silane production. Such a lower grade of silane may be available at about 30% lower cost than seven nines silane and make possible a 30% higher production capacity.

In these and other aspects, a silane specification (sometimes referred to herein as a lower specification silane) may include 20 parts per million (ppm) nitrogen impurity in a silicon film made from the silane. The N₂ level of impurity in the silane reagent may be less than about 5%. In some other aspects, the N₂ level of impurity in the silane reagent may be less than about 1-3%. As discussed above, other impurity types and/or levels may be present in a lower specification silane reagent, such as, for example, di-silane, tri-silane, poly-silane and/or other silicon species such as, for example, SiF4. A silane specification may therefore include up to about 4000 ppm SiF₄, up to about 3000 ppm SiF₄, or up to about 2000 ppm SiF₄.

In these and other aspects, water may be present in the silane reagent at less than or equal to about 10 ppm. In some other aspects, water may be present in the silane reagent at less than or equal to about 1 ppm. Other water amounts may be present.

In these and other aspects, dopant impurities in non-doped silicon films made from the silane may be acceptable at less than about 10¹³-10¹⁴ dopant atoms/cc. Doped silicon films may contain about 10¹⁹-10²¹ dopant atoms/cc. Other dopant levels may be employed.

Thus, in some aspects, the silane plant purification bottleneck may be removed by keeping the current purity targets for N₂ and halogens, and not limiting silane compounds such as, but not limited to, di-silane, tri-silane, dichlorosilane and trichlorosilane. In this way, silane production may be increased and silane cost may be decreased.

In additional aspects, the present invention provides methods for forming silicon layers on substrates such as glass or other insulators. In one step, a substrate may be provided. In another step, hydrogen and silane may be introduced into a chamber which may contain the substrate, such that an amorphous layer of silicon may be deposited on the substrate. The silane in this aspect may be less than or equal to about 99.999% pure, less than about 99.99% pure, less than about 99.9% pure, less than about 99% pure, less than 98% pure, and/or less than about 95% pure. In another similar aspect, the method differs in that the hydrogen and silane may be introduced into a chamber which contains the substrate such that a micro-crystalline layer of silicon is deposited on the substrate.

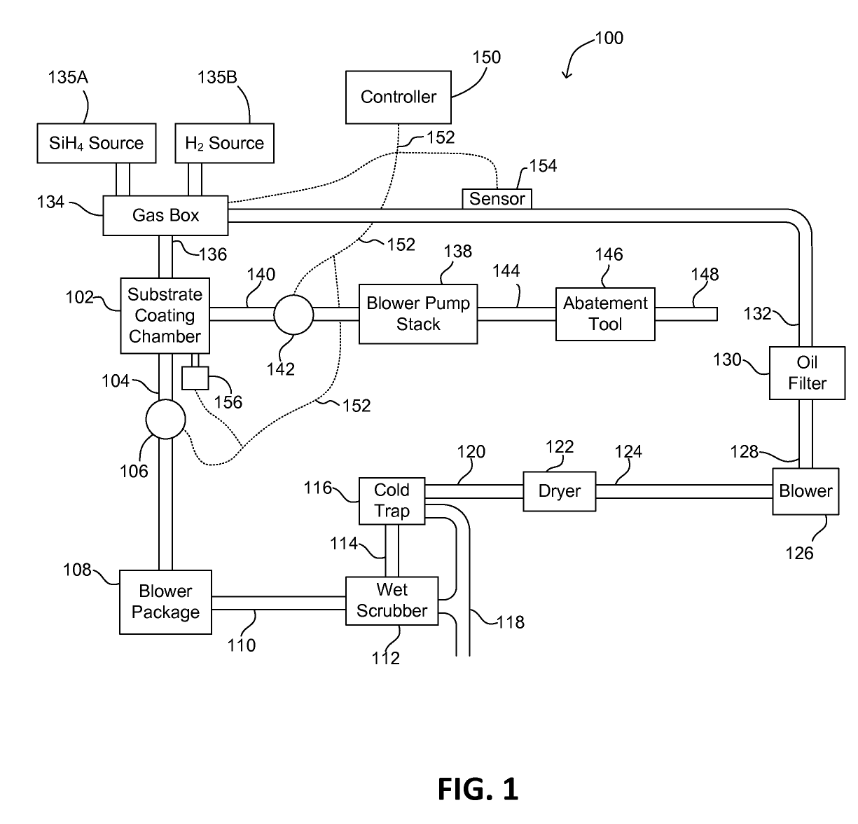

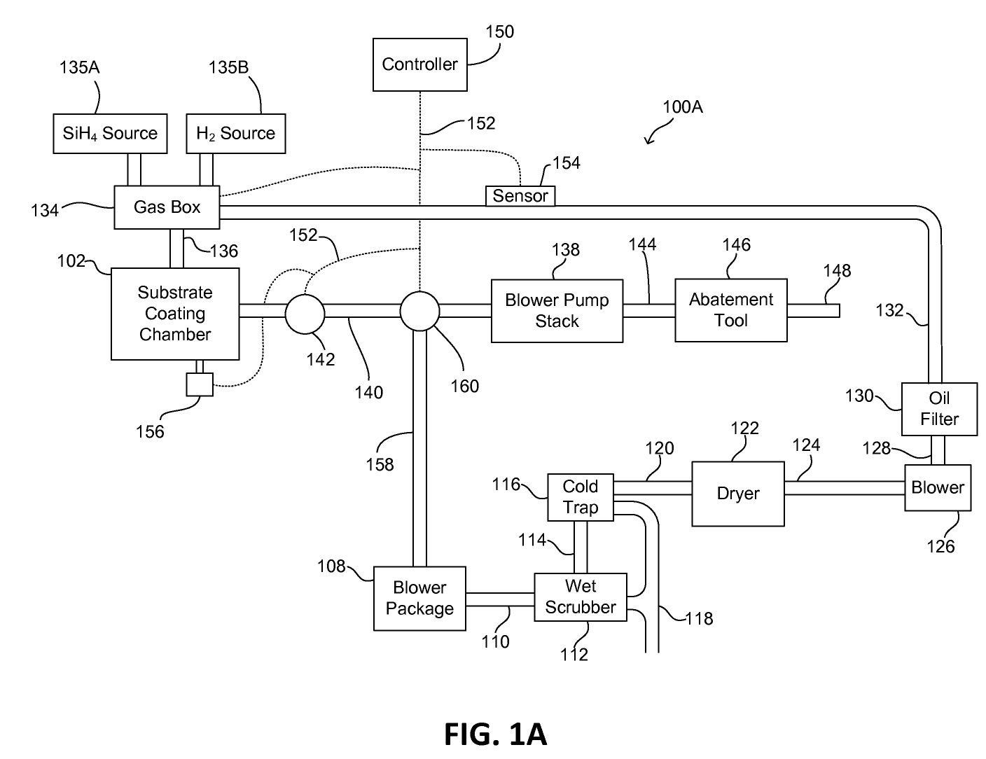

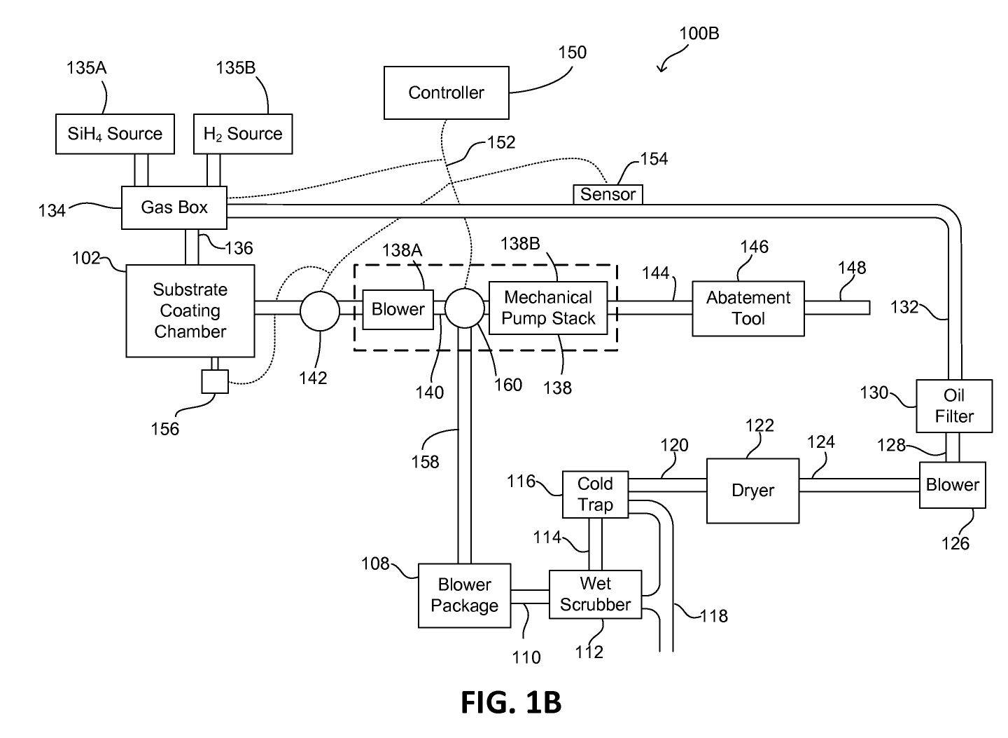

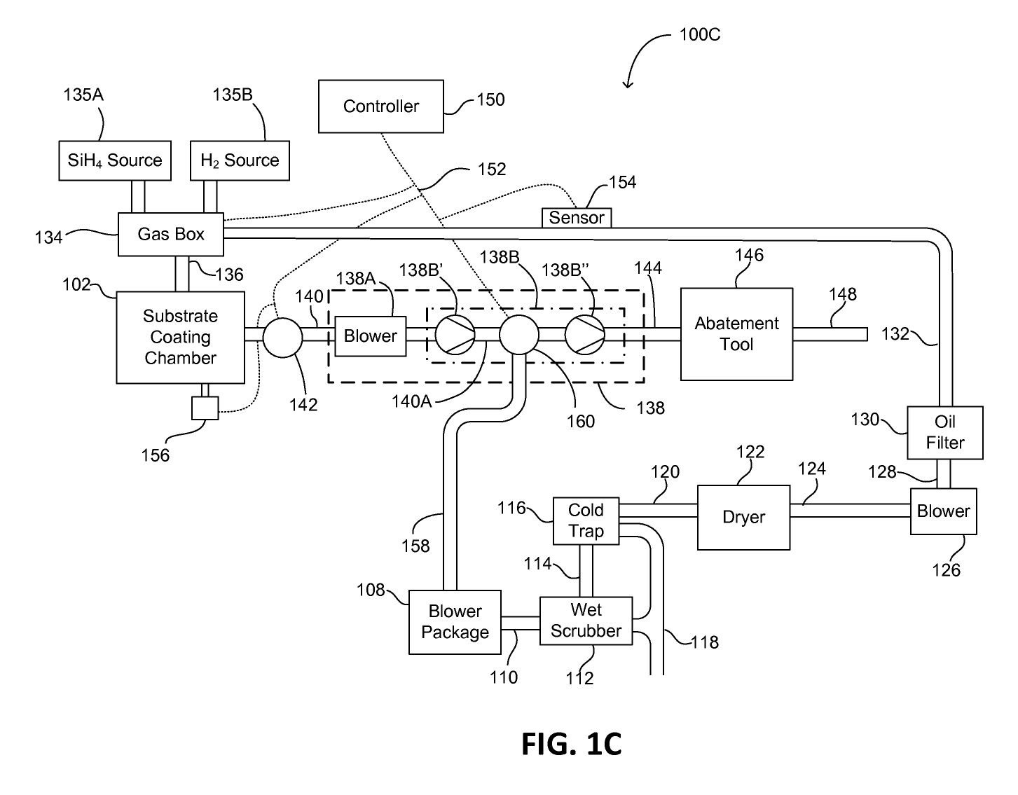

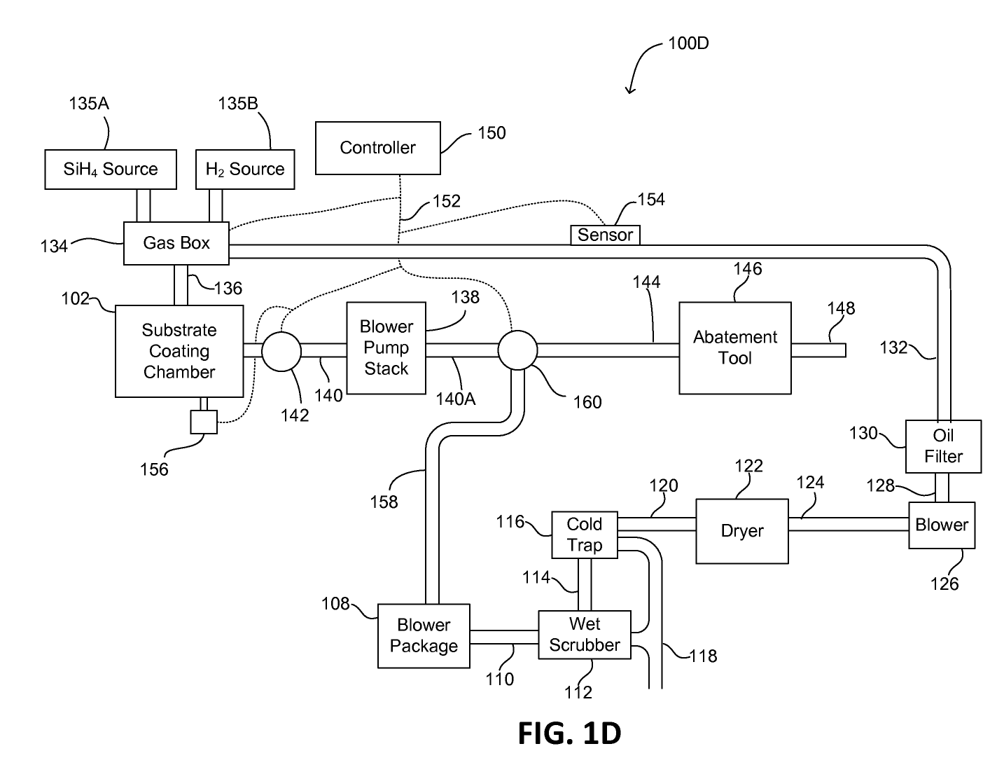

FIG. 1 is a schematic drawing of a substrate coating system 100 of the present invention adapted to reclaim and reuse hydrogen as a reagent in a substrate coating process. System 100 may include a substrate coating chamber 102 which may be used to coat substrates. For example, in the production of solar panels, it is common to coat a substrate such as glass with silicon to form a polysilicon coating on the glass. Substrates other than glass may be used, for example, metals, films, polymers, etc. System 100 may be used in coating processes which are employed in electronic device manufacturing other than solar panel manufacturing.

Substrate coating chamber 102 may be connected through conduit 104 and throttle valve 106 to blower package 108. Blower package 108 may include low pressure water cooled blowers, although non-water cooled blowers may be used as well. The blowers may be lower tolerance blowers than the blowers typically used to evacuate process chamber effluent for the purpose of abatement, and may provide the benefits of less energy being needed to run the blowers and less heat being transferred to the gasses being moved by the blowers. In embodiments wherein more than one blower (optionally water cooled) may be used in blower package 108, the blowers may be staged so as to increase the pressure of the recycle stream while imparting a reduced amount of heat to the recycle stream. Any blowers or pumps which can increase the pressure of the recycle stream to, for example, between about 10 to about 40 p.s.i., about 20 to about 30 p.s.i. or about 10 to about 20 p.s.i., may be used. Other higher and lower pressures may be used. The blowers may reduce or eliminate the transmission of any back pressure waves from downstream of the blower package 108 to upstream of the blower package 108. Such back pressure waves may interfere with coating processes taking place in the substrate coating chamber 102.

Blower package 108 may be connected through conduit 110 to wet scrubber 112. Scrubber 112 may be, for example, a bubble tower, burr saddle, packed bed tower, or scrubbing tower. Any suitable wet scrubber may be used.

Scrubber 112 may be connected through conduit 114 to cold trap 116. Cold trap 116 may include one or more refrigerated plates or other surfaces upon which gases which are to be removed from a gas stream may condense, the impurities thus condensing out of the recycle stream. In yet other embodiments, the separation unit may be a filter or a chilled ceramic or metal filter, such as, for example, a sintered nickel filter, and may be located downstream from the recycle blowers. Combinations of the foregoing separation units may also be used.

The cold trap 116 is capable of trapping and retaining particles and high molecular weight species. In embodiments which comprise a cold trap separator upstream from the recycle blowers, a remote plasma (not shown) may be used to clean the cold trap and the recycle blowers. If the cold trap is located downstream of the recycle blowers, a remote plasma may be used to clean the cold trap. The remote plasma generator may utilize either NF₃ or F₂ from the chamber clean cycle, or the NF₃ or F₂ may be from a different source. In some of these embodiments, the recycle stream may comprise two parallel streams (not shown), each of which pass through a cold trap/recycle blower set. In these embodiments, one cold trap/recycle blower set may be cleaned while the other set is being operated. The cold trap 116 may be adapted to be isolated and bypassed to facilitate maintenance (not shown). The two sets may be alternately cleaned and used.

In other alternative embodiments, instead of cryogenic or cold trap methods, high surface area packing, pressure swing adsorption, temperature swing adsorption, chemical, ceramic or metal filters may be used to polish (e.g., purify) reclaim gases. Single or double beds may be useful.

Scrubber 112 and cold trap 116 may be connected to a water treatment unit (not shown) through conduit 118. Silicon species which may be present in the effluent which passes through a wet scrubber 112 may be recovered in such a water treatment unit.

The cold trap 116 may be connected through conduit 120 to dryer 122. The dryer 122 may be a molecular sieve dryer, or any other suitable dryer. The dryer 122 may be a single or a multiple bed dryer.

The dryer 122 may be connected through conduit 124 to blower 126. Blower 126 may be similar to a blower used in the blower package 108. Blower 126 may be connected through conduit 128 to oil filter 130. Oil filter 130 may be used to trap any oil, contaminant, lubricant reaction products, and or any other high vapor pressure material which may be imparted to the reagent stream from blower stack 126.

Oil filter 130 may be connected through conduit 132 to gas box 134. Alternatively, oil filter 130 may be connected through conduit 132 to a buffer tank (not shown).

The gas box 134 may be used to mix reagent and other gases for introduction through conduit 136 into substrate coating chamber 102. The gas box 134 may be configured such that it is connected to reagent sources, such as silicon source 138A and hydrogen source 135B and other gas sources (not shown). The reagent and other gases may be introduced into the gas box through mass flow controllers (not shown) which may form part of the gas box 134, so that precise mass flow rates of reagent and other gases may be introduced into the substrate coating chamber 102.

The substrate coating chamber 102 may also be connected to blower pump stack 138 through conduit 140 and isolation valve 142. The blower pump stack 138, which may be comprised of one or more blowers (not shown in FIG. 1) and one or more mechanical pumps (not shown in FIG. 1) may be connected through conduit 144 to abatement tool 146.

The abatement tool 146 may be a burn wet abatement tool, or an electro-thermal abatement unit, etc. Any abatement tool which is effective to abate chamber cleans, which may contain fluorine species, may be used. The abatement tool 146 may be connected through conduit 148 to a house exhaust system (not shown), further abatement treatment on (not shown), or to the atmosphere.

System controller 150 may be connected through communication lines (or communication network) 152 to the gas box 134, valve 142, the valve 106, the composition sensor 154 and pressure control sensor 156. System controller 150 may be any microcomputer, microprocessor, process logic controller, logic circuit, a combination of hardware and software, or the like. Communication lines/network 152 may be an Ethernet network, a standard communication bus or signal connector cables. Any suitable communication link may be used. Sensor 154 may be a quadrupole mass spectrometer residual gas analyzer (QMS RGA) sensors, Fourier Transform Infrared (FTIR) sensors, chemiluminescence sensors, or any other sensors suitable for detecting hydrogen, silane, and or other species.

The following description of the operation of system 100 uses a process for coating silicon on a substrate as an example. It should be understood, however, that the invention is not limited to coating silicon on a substrate, but, rather, may be used in any electronic device manufacturing process where a reagent may pass unused through a process chamber. Examples include deposition applications for solar panels, liquid crystal displays, organic light emitting diodes, film, and nanomanufacturing, etc. In addition, the invention may be used for process chambers which may be used to etch patterns to remove unwanted materials and/or to clean surfaces, etc.

In operation, the substrate coating chamber 102 may be operated in at least two modes. In a first mode, the substrate coating chamber 102 may perform a coating process whereby a substrate may be coated with silicon, for example. During this mode, excess silane and hydrogen reagents may pass from the coating chamber 102 as effluent, and it may be desirable for reclaim and recycle the reagent gases. In a second mode, the substrate coating chamber 102 may be cleaned with a plasma, such as a fluorine plasma, for example. During clean modes, it may be desirable to simply abate effluent which passes from the coating chamber 102.

In the first mode, the deposition mode, the gas box 134 may receive hydrogen and silane gases from silane source 135A and hydrogen source 135B. Silane source 135A and hydrogen source 135B may be cylinders, facility supplies, or any other suitable supplies of silane and hydrogen. The gas box 134 may in turn supply precise amounts of silane and hydrogen gases to the substrate coating chamber 102, using mass flow controllers (not shown), for example.

During the coating process, the pressure in the substrate coating chamber 102 may be regulated by a pressure control subsystem comprising pressure gauge 156, controller 150, valve 106, blower package 108, and the introduction of gases to the process chamber 102 from the gas box 134. The blower package 108 may provide a source of vacuum through conduit 104. During the deposition mode, the valve 142 may be in a closed position so that effluent silane and hydrogen do not pass to the abatement tool 146. Instead, during the coating process, the effluent hydrogen and silane gases may be evacuated from the coating chamber 102 for reclaim and recycling by blower package 108 through conduit 104, throttle valve 106 and conduit 110, and passed into scrubber 112.

The effluent hydrogen and silane reagents may optionally contact water in scrubber 112 or staged cryogenic filters or cold traps (not shown in FIG. 1) which may have the effect of removing silane, di-silane, tri-silane, poly-silane and/or other silicon species such as, for example, SiF4 from the gas stream. In addition, scrubber 112 or optional staged cryogenic filters or cold traps may remove dopants which may exist in the effluent gas stream. The silane, di-silane, tri-silane, poly-silane, dopants and/or other silane species may exit the scrubber in scrubber medium through conduit 118. The remaining gas stream may then pass through conduit 114 into cold trap 116. The cold trap 116 may have the effect of removing any remaining particles, water, silane, di-silane, tri-silane, poly-silane, dopants and/or other silane species which may remain in the gas stream. The effluent gas stream may then pass from the cold trap 116 through conduit 120 into dryer 122, where the gas stream may be dried to less than about 2 ppm water. Blower 126 may then motivate the gas stream to move from dryer 122 through conduits 124, 128 and oil filter 130 where any oil or other high molecular weight and/or high vapor pressure species which may have been imparted to the gas stream from blower 126 and/or blower package 108 may be removed. At this stage, the gas stream may be a hydrogen gas stream which may then be supplied to gas box 134 for reuse as a reagent in the substrate coating process conducted in substrate coating chamber 102.

The system 100 may also recertify the reclaimed hydrogen. Thus, gas sensor 154 may be located in line to provide the controller 150 with information regarding the chemical make-up of the recycle gases through communication network 152. The process controller may then, if necessary, command the gas box 134 through communication network 152 to cause virgin or make-up hydrogen feed stocks to be added to the hydrogen recycle gas to bring the gas up to a predetermined specification for use in the substrate coating process chamber. In addition to continuous recertification, recertification may be done in a batch process where the recycle gases are stored prior to remixing with new feed stocks (not shown).

Sensor 154 may optionally be eliminated. The purity of the hydrogen stream in conduit 132 over the course of the deposition, and then the clean cycles, may either be calculated, or may be known through experience. The controller 150 may therefore be programmed to command the gas box 134 to mix in an appropriate amount of make-up hydrogen without the use of a real time sensor 154.

The silane, di-silane, tri-silane, poly-silane and/or other silane species which may flow through conduit 118 may be collected using filters, for example, and may be used as precursor materials for silane production (not shown). Any suitable method or apparatus for separating the silane, di-silane, tri-silane, poly-silane and/or other silane species from the scrubber medium may be used.

In the second mode, the cleaning mode, the substrate coating chamber may be cleaned with a plasma from a remote plasma source (not shown). This plasma clean may be motivated by blower pump stack 138 to move through conduit 140, valve 142 and conduit 144 into abatement tool 146, where the plasma clean may be abated. From the abatement tool 146, the abated plasma clean may pass through conduit 148 into a house scrubber (not shown), further abatement (not shown), or to the atmosphere. During the cleaning mode, the valve 106 may be in a closed position.

FIG. 1A is a schematic drawing of an alternative configuration of the substrate coating system 100 of FIG. 1, substrate coating system 100A. System 100A may be similar to the system 100 of FIG. 1 with the exception of the connection between the blower package 108 and the substrate coating chamber 102, and the inclusion of a control system. Instead of the blower package 108 being connected directly to the substrate coating chamber 102, as depicted in FIG. 1, the blower package 108 may be connected through conduit 158 and three way valve 160 to conduit 140. Conduit 140 may be a vacuum line which connects blower pump stack 138 to the substrate coating chamber 102. Controller 150 may be connected through signal lines 152 to the sensor 154, the gas box 134, the valve 142, and the three way valve 160.

In operation, system 100A may operate similarly to system 100 of FIG. 1, with the exception that during the coating or deposition mode, unused reagent gases may not pass into conduit 104 as the reagent gases may in the system 100 of FIG. 1. Instead, the reagent gasses may pass into conduit 140, and then be diverted by valve 160 through conduit 158 into blower package 108. During the chamber clean mode, the valve 160 may be configured such that the chamber clean may pass through conduit 140 into blower pump stack 138.

The controller 150 may determine whether the substrate coating chamber 102 is in the clean mode or in the deposition mode, and may appropriately configure three way valve 160.

FIG. 1B is a schematic drawing of an alternative configuration of a substrate coating system 100B of the present invention. The system 100B may be similar to the system 100A, with the exception of a location of the blower package 108 connection to the conduit 140. Whereas, in FIG. 1A the blower package 108 is depicted as connected to the conduit 140 prior to the blower pump stack 138, in FIG. 1B, the blower package 108 is depicted as connected to conduit 140 through valve 160 between the blower 138A and the mechanical pump stack 138B components of the blower pump stack 138. In an alternative embodiment, blower package 108 may be eliminated, because the system 100B may rely on the blower 138A to prevent back pressure waves from passing through to the substrate coating chamber 102.

In operation, the system 100B may operate similarly to the system 100A of FIG. 1A, with the following exceptions. In embodiments wherein blower package 108 is eliminated, blower 138A may provided the motive force for effluent to move through valve 160 and conduits 158, 110 to wet scrubber 112.

FIG. 1C is a schematic drawing of an alternative configuration of a substrate coating system 100C of the present invention. The system 100C may be similar to the system 100B of FIG. 1B, with the following exceptions. Whereas in FIG. 1B the optional blower package 108 is depicted as connected to conduit 140 between the blower 138A and the mechanical pump stack 138B components of the blower pump stack 138, in FIG. 1C the optional blower package 108 is connected to conduit 140A through valve 160 between mechanical pumps 138B′, 138B″ of mechanical pump stack 138B.

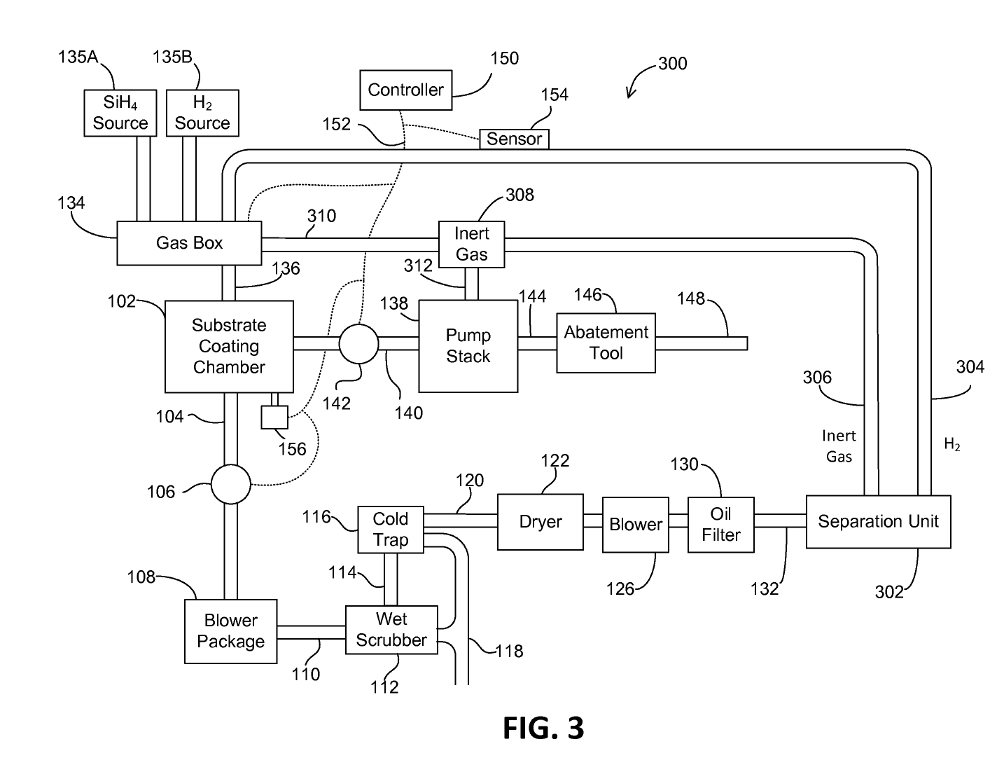

As will be discussed in more detail below with respect to FIG. 3, an inert gas such as nitrogen, for example, may typically be added to the effluent gas stream before, or as, it passes through the mechanical pump stack in order to facilitate the pumping of hydrogen (not shown). The addition point of the inert gas may be before any of the mechanical pumps 138B′, 138B″. Note that, although only two mechanical pumps 138B′, 138B″ are shown in FIG. 1C, either more or fewer mechanical pumps may be employed.

In operation, the system 100C may operate similarly to the system 100B of FIG. 1B.

FIG. 1D is a schematic drawing of an alternative configuration of a substrate coating system 100D of the present invention. The system 100D of FIG. 1D may be similar to the system 100B of FIG. 1B and the system 100C of FIG. 1C, with the following difference. In the system 100D, the optional blower package 108 may be connected to the conduit 140A downstream from the blower pump stack 138.

In operation, the system 100D may operate similarly to the systems 100B and 100C.

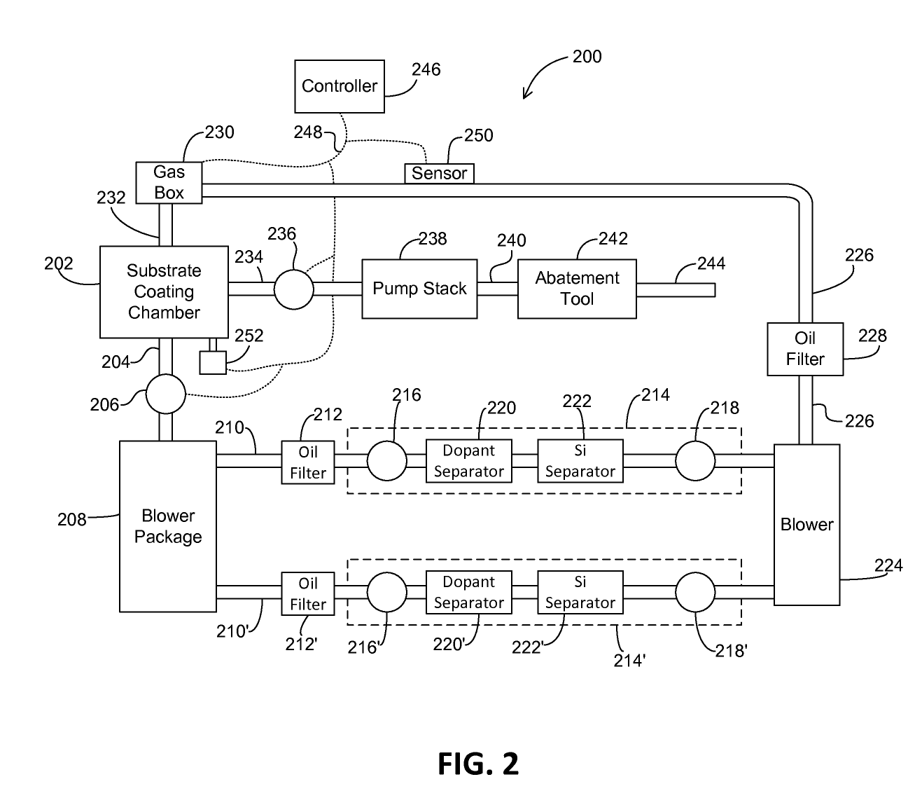

FIG. 2 is a schematic drawing of a substrate coating system 200 depicting another embodiment of the present invention. System 200 may include a substrate coating chamber 202 which may be used to coat substrates. The substrate coating chamber 202 may be similar to the substrate chamber 102 of FIG. 1. The substrate coating chamber 202 may be connected through conduit 204 and valve 206 to blower package 208. The valve 206 may be a throttle valve. Blower package 208 may be similar to blower package 108 of FIG. 1.

Blower package 208 may be connected through conduits 210, 210′ and oil filters 212, 212′ to separation systems 214, 214′. Oil filters 212, 212′ may be similar to oil filter 130 of FIG. 1. Although two separation systems 214, 214′ are shown in FIG. 2, it is to be understood that fewer or more separation systems may be used (e.g., 1, 3, 4, etc.).

Separation system 214 may include isolation valves 216, 218; dopant separator 220; and silicon separator 222. Isolation valves 216, 218 may be used to isolate separation system 214 from system 200. Dopant separator 220 may be an absorption separation matrix or an adsorption separation matrix. Alternatively, the dopant separator 220 may be replaced with a dopant filter (not shown). Similarly, the silicon separator 222 may be an absorption separation matrix or an adsorption separation matrix, or, alternatively, silicon separator 222 may be a silicon filter. A suitable filter may be a honeycomb ceramic matrix which is coated with silicon. The ceramic may be an yttria doped alumina. Separation system 214′ may be similar to separation system 214.

Separation systems 214, 214′ may be connected to blower 224. Blower 224 may be connected through conduit 226 and oil filter 228 to gas box 230. Gas box 230 may be connected through conduit 232 to substrate coating chamber 202.

Substrate coating chamber 202 may also be connected through conduit 234 and isolation valve 236 to pump stack 238. Pump stack 238 may be connected through conduit 240 to abatement tool 242. Abatement tool 242 May be connected through conduit 244 to a house exhaust system (not shown), further abatement treatment (not shown), or to the atmosphere, etc.

Controller 246 may be connected, through communication network 248 to the gas box 230, the valve 236, the valve 206, the composition sensor 250 and pressure sensor 252.

Although not shown, the system 200 may be modified in a manner similar to the manner in which the system 100 may be modified to form system 100A. Such a modification may include connecting the blower package 208 to the effluent conduit 234 through a three way valve (not shown) located between the throttle valve 236 and the pump stack 238, for example, which would be adapted to divert gas flow between the pump stack 238 and the blower package 208, depending upon whether the chamber was in a clean mode or a deposition mode, respectively. The controller may be used to control the three way valve (not shown) so that chamber cleans may be directed to the abatement tool 242, while effluent reagents may be directed to blower package 208 for reclaim and recycling. Analogously, the system 200 may also be modified in manners similar to the manners in which the system 100 may be modified to form the systems 100B, 100C, and 100D.

In operation, substrate coating chamber 202 may operate similarly to substrate coating chamber 102 of FIG. 1, with the exception that in the deposition mode the unused reagents may not be passed through a wet scrubber, a cold trap, and a dryer, as they are in system 100 of FIG. 1. Instead, the unused reagents (and any dopants) may be passed from blower package 208 through conduits 210, 210′, through oil filters 212, 212′ and into separation systems 214, 214′.

Separation systems 214, 214′ may remove dopants from the unused reagent gas stream with dopant separators 220, 220′, which, as described above, may be absorption or adsorption separation matrices. The dopants may be collected, separated if necessary, and reused as dopants.

Separation systems 214, 214′ may remove silicon compounds from the unused gas stream using silicon separation units 222, 222′. Silicon separators 222, 222′ may remove silicon, silane, di-silane, tri-silane, and poly-silane through mechanisms of absorption, adsorption, and/or filtration. The silicon, silane, di-silane, tri-silane, and poly-silane which may be removed from the unused reagent gas stream may be collected and sent, or sent directly, to a silane manufacturing facility, which may supply silane to the gas box 230 for use as a substrate in substrate coating chamber 202.

The net result of the unused reagent gas stream passing through separation systems 214, 214′ may be that the unused reagent gas which flows from the separation systems 214, 214′ into blower 224 may include high purity hydrogen gas. The high purity hydrogen gas may flow through conduit 226 and oil filter 228 (where any oil or other high molecular weight contaminant introduced into the hydrogen gas by blower 224 may be removed), and into gas box 230.

The remainder of the system 200 of FIG. 2, including recycle of hydrogen through conduit 226, may operate similarly to the system 100 of FIG. 1.

FIG. 3 is a schematic depiction of a substrate coating system 300 of the present invention. The system 300 may be similar to the system 100 of FIG. 1, with the following exceptions. In system 300, the oil filter 130 may not be connected through conduit 132 to gas box 134 as it is in the system 100 of FIG. 1. Instead, the oil filter 130 may be connected through the conduit 132 to separation unit 302. The separation unit 302 may be a membrane separator which may be adapted to separate hydrogen gas from an inert gas. Any suitable separator may be used. The separation unit 302 may be connected through conduit 304 to the gas box 134 and through conduit 306 to an inert gas source 308. The inert gas source 308 may be connected through the conduit 310 to the gas box 134, and through conduit 312 to pump stack 138.

In operation, the system 300 may operate similarly to the system 100 of FIG. 1, with the following exceptions. In the system 300, inert gas may be introduced into the gas box 134 from the inert gas source 308 through the conduit 310. The inert gas may be nitrogen, helium, argon, etc. or any other suitable inert gas. The inert gas may be used to cool the substrate coating chamber 102. An additional benefit may be more efficient utilization of reagents such as silane and hydrogen. The inert gas may pass with the unused reagents through the system until the inert gas enters conduit 132 with otherwise highly pure hydrogen gas. The inert gas/hydrogen gas mixture may then enter separation unit 302 which may separate the hydrogen gas from the inert gas. The hydrogen gas may then pass from the separation unit 302 through the conduit 304 and into the gas box 134. The inert gas may pass from the separation unit 302 through the conduit 306 into the inert gas source 308, from which it may be sent through the conduit 310 into the gas box 134.

In addition, the inert gas source 308 may supply inert gas to the mechanical pumps (not shown) of the pump stack 138 through conduit 312.

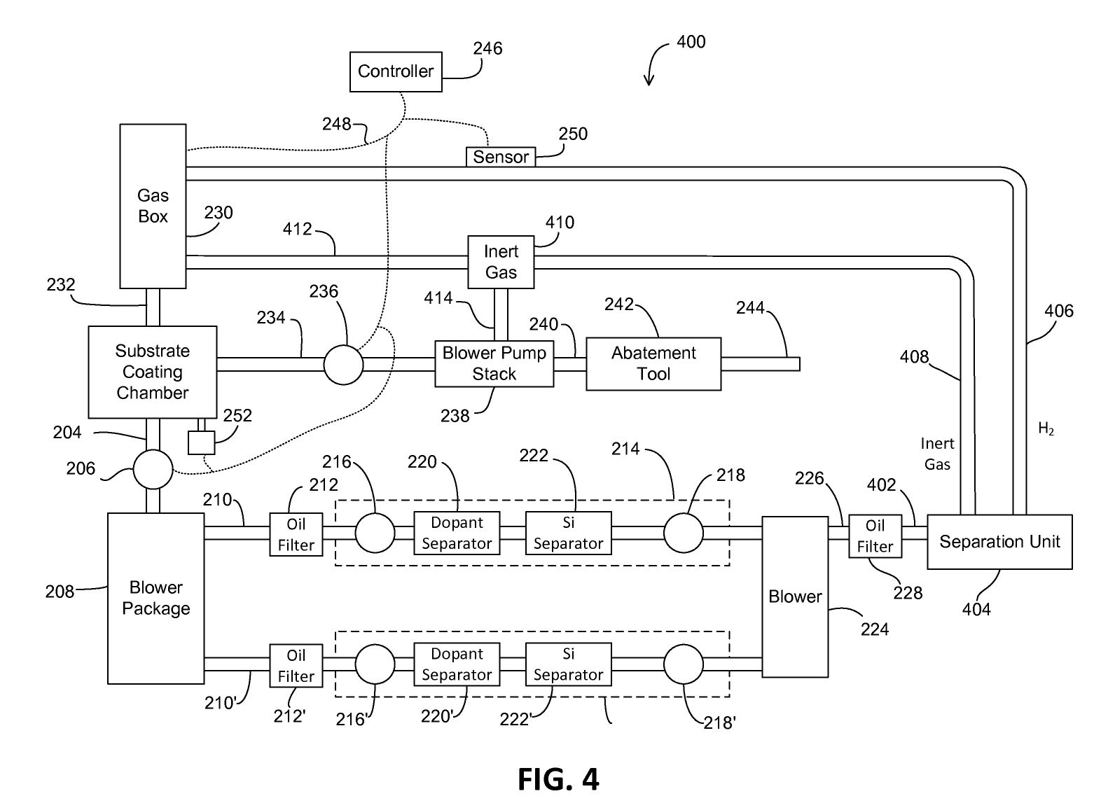

FIG. 4 is a schematic depiction of a substrate coating system 400. System 400 may be similar to the system 200 of FIG. 2, with the following exceptions. In system 400, the oil filter 228 may not be connected through the conduit 226 to the gas box 230 as it is in system 200 of FIG. 2. Instead, the oil filter 228 may be connected through conduit 402 to separation unit 404. The separation unit 404 may be similar to the separation unit 302 of FIG. 3. The separation unit 404 may be connected through conduit 406 to the gas box 230. The separation unit 404 may also be connected through the conduit 408 to inert gas source 410. The inert gas source 410 may be connected through conduit 412 to gas box 230. The inert gas source 410 may also be connected through conduit 414 to the blower pump stack 238.

In operation, the system 400 may operate similarly to the operation of the system 200 of FIG. 2, with the following changes and additions. In the system 400, inert gas may be introduced into the gas box 230 from the inert gas source 410 through the conduit 412. As in the system 300 of FIG. 3, the inert gas may be nitrogen, helium, argon, etc. or any other suitable inert gas. The inert gas may have the same effects on the system 400 as the inert gas has on the system 300 of FIG. 3. As in the system 300, the inert gas may pass with the unused reagents through the system until the inert gas enters the conduit 402 with hydrogen gas. The inert gas/hydrogen gas mixture may then enter the separation unit 404 which may separate the hydrogen gas from the inert gas. The hydrogen gas may then pass from the separation unit 404 through the conduit 406 into the gas box 230. The inert gas may pass from the separation unit 404 through the conduit 408 into the inert gas source 410 from which the inert gas may be sent through the conduit 412 into the gas box 230. The inert gas may also pass through conduit 414 to the blower pump stack 238 to facilitate the pumping of hydrogen.

The system 400, like the system 100, may also recertify the reclaimed hydrogen. Thus, gas sensor 250 may be located in line to provide the controller 246 with information regarding the chemical make-up of the recycle gases through communication network 248. The process controller may then, if necessary, command the gas box 230 through communication network 248 to cause virgin hydrogen feed stocks to be added to the hydrogen recycle gas to bring the gas up to a predetermined specification for use in the substrate coating process chamber. In addition to continuous recertification, recertification may be done in a batch process where the recycle gases are stored prior to remixing with new feed stocks (not shown).

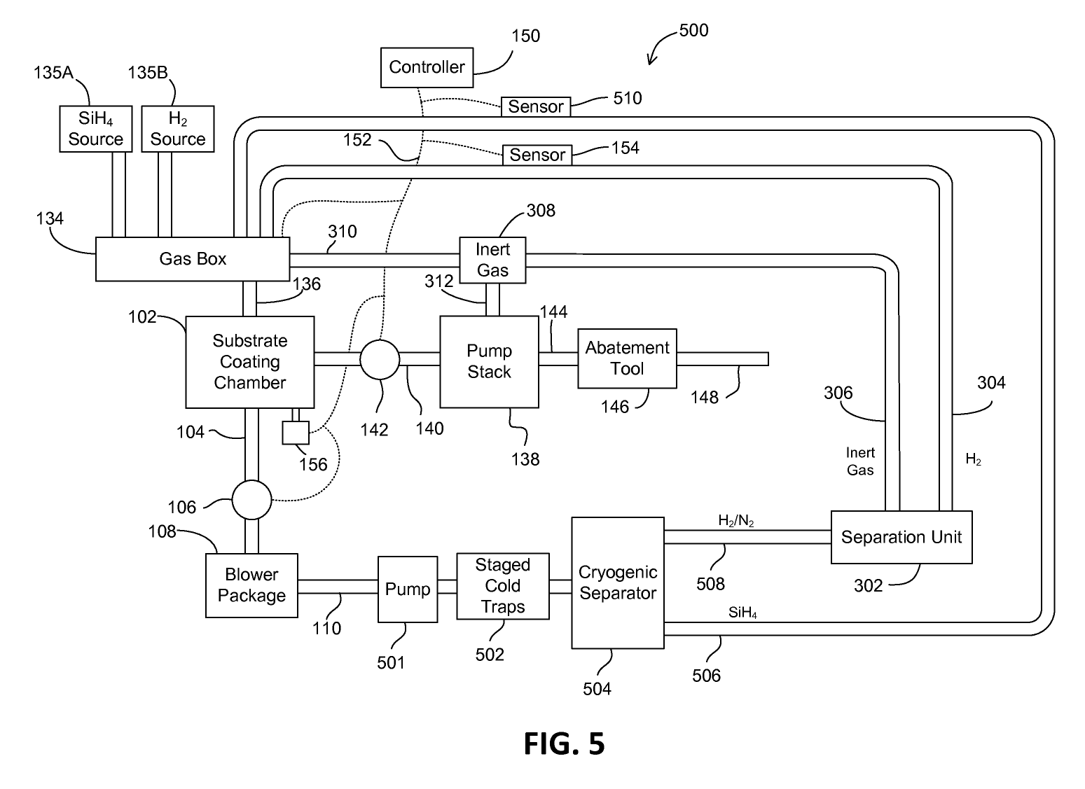

FIG. 5 is schematic depiction of a substrate coating system 500 of the present invention. The system 500 may be similar to the system 300 of FIG. 3, with the following differences. System 500 may not employ the wet scrubber 112 and cold trap 116 to separate silane and other silicon species from the effluent stream. Instead, coating system 500 may employ pump 501 to move the effluent stream through staged cold traps or cryogenic filters 502 which may remove heavier silicon species, such as di-silane, tri-silane, and SiF₄ from the stream, while leaving silane in the stream. The resulting effluent stream may contain silane, hydrogen and inert gas when it enters cryogenic separator 504. The cryogenic separator 504 may comprised liquid nitrogen chilled plates, or any other cryogenic separator capable of separating silane from hydrogen and/or nitrogen. The cryogenic separator 504 may separate silane from hydrogen and an inert gas such as nitrogen, flowing silane through conduit 506 to the gas box 134 and hydrogen/inert gas through conduit 508 into separation unit 302. Although not shown, conduits 506, 508 may incorporate pumps to facilitate the movement of the gas streams therein. Conduit 506, may also be connected to sensor 510. Sensor 510 may be similar to sensor 154, and may be connected to controller 150 through network 152.

Although only one pump 502, staged cold traps 502 and cryogenic separator 504 are depicted in FIG. 5, it should be understood that more than one pump 502, staged cold traps 502 and cryogenic separator 504 may be used in parallel so that one set may be taken out of service for maintenance without interrupting operation of the coating system 500.

In some embodiments, the separation unit may be a cryogenic separator, which is capable of separating the impurities from the silane and hydrogen, and also of separating the silane from the hydrogen. The cryogenic separator may be located downstream of the recycle blowers. In other embodiments, the separation unit may be a cold trap separator, which may be located upstream or downstream from the recycle blowers.

In operation, coating system 500 may operate in a manner similar to the manner in which coating system 300 operates, with the following differences. A coating chamber effluent stream may pass through pump 501 into staged cold traps 502 and cryogenic separator 504. The staged cold traps 502 may be arranged to remove successively lighter molecules from effluent stream so that di-silane and tri-silane may be removed first, then SiF₄ may be removed. The cryogenic separator 504 may separate the coating chamber effluent stream into a silane stream which may be channeled through conduit 506 to the gas box 134, and a hydrogen/inert gas stream which may be channeled through conduit 508 to separation unit 302. The operation of coating system 500 with respect to the hydrogen/inert gas stream following the separation unit 302 may operate in a manner similar to the operation of coating system 300.

As discussed above, the silane stream which may flow through conduit 506 to the gas box 134, may not be sufficiently pure to meet a predetermined silane specification for use in the substrate coating chamber 102. Sensor 510 may determine the composition of the silane stream flowing through conduit 506 and report such composition to the controller 150. The controller 150 may then calculate an amount of virgin silane which needs to be added to the recycle silane and the gas box 134 to add a sufficient amount of silane from silane source 135A to bring the resulting silane/virgin silane mixture up to the predetermined specification.

Sensor 510 may optionally be eliminated. The purity of the silane stream in conduit 506 over the course of the deposition, and then the clean cycles, may either be calculated, or may be known through experience. The controller 150 may therefore be programmed to command the gas box 134 to mix in an appropriate amount of make-up silane without the use of a real time sensor 510.

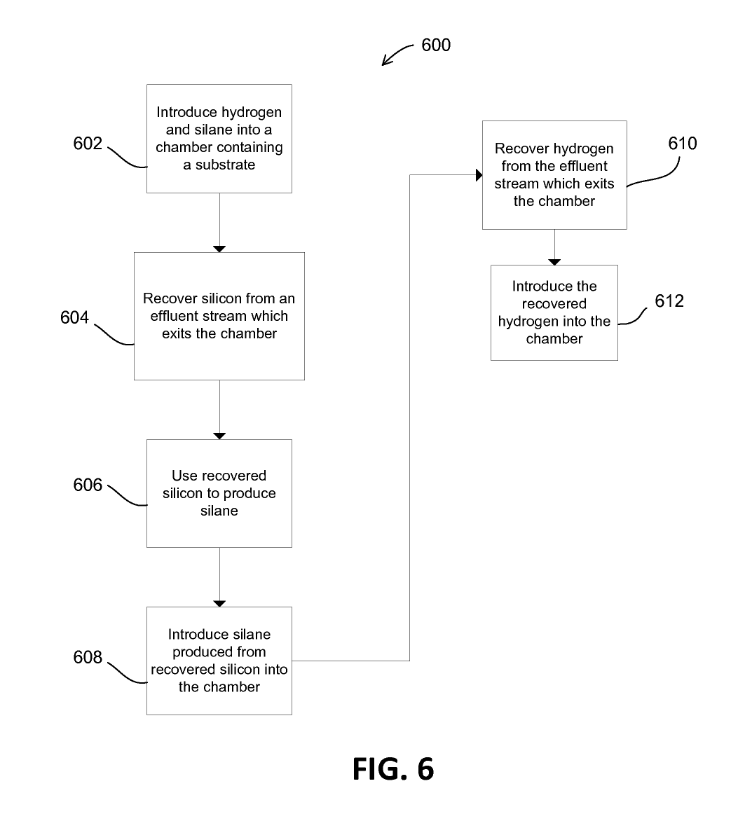

FIG. 6 is a flow chart depicting a method 600 of the invention for forming a silicon layer on a substrate. In step 602, hydrogen and silane are introduced into a chamber containing a substrate under process conditions adapted to form a silicon layer on the substrate. In step 604, silicon is recovered from an effluent stream which exits the chamber. As explained above, a majority of the silane which is introduced into the chamber may typically exit the chamber as effluent, in the forms of silicon species such as, e.g., silane, di-silane, tri-silane, and poly-silane, and/or other silicon species, etc. The method 600 may be practiced on, but is not limited to, coating systems 100, 100A, 100B, 100C, 100D, 200, 300, 400 and 500. In step 606, the silicon species is/are used to produce silane for use as a reagent in the coating chamber. Any known or yet to be discovered methods for producing silane from the silicon species precursors may be used. In step 608, the silane produced from the recovered silicon species is provided to a gas box which, in turn, introduces the silane into the deposition chamber. In optional step 610, hydrogen is recovered from the deposition chamber effluent stream. The hydrogen may be processed, such as, for example, by filtering, drying, etc. It is to be understood that although this example is presented in the form of a deposition system, the chamber may be used to perform any suitable process where unused reagents or elements exit from the chamber in an effluent stream. In optional step 612, the recovered hydrogen is provided to the gas box from which the recovered hydrogen may be introduced into the silicon coating chamber. Alternatively, the recovered hydrogen may be used to produce methane. The methane may then be introduced, with or without hydrogen, into the silicon coating chamber along with silane.

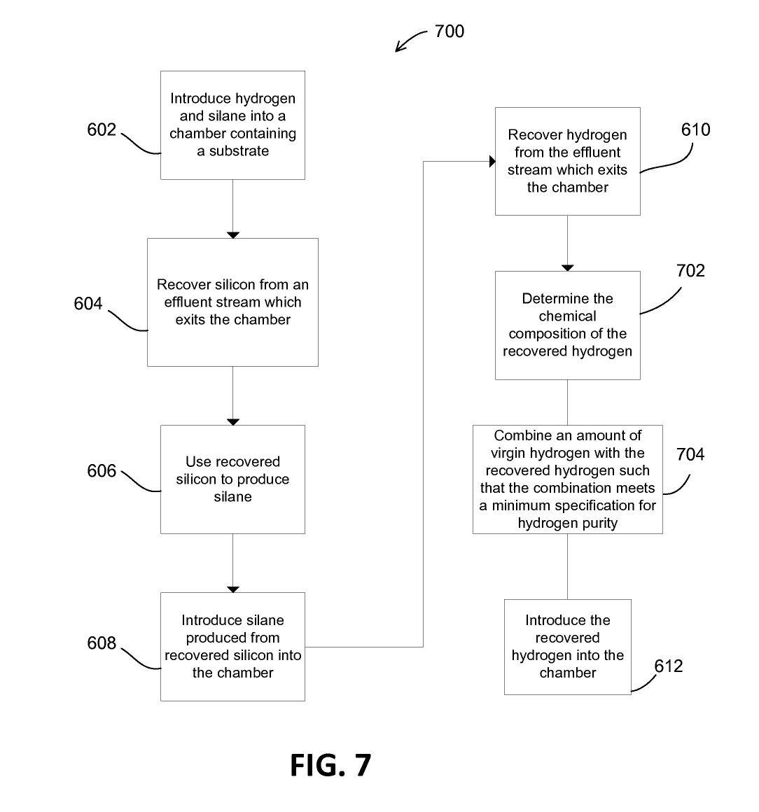

FIG. 7 is a flow chart depicting another method 700 of the invention for forming a silicon layer on a substrate. Method 700 may be similar to method 600, with the addition of the following steps. In step 702, the chemical composition of the hydrogen which is recovered from the effluent stream which exits the deposition chamber in step 610 is tested for composition and/or purity. Any suitable sensor may be used to determine the composition and/or purity of the recovered hydrogen, including a quadrupole mass spectrometer residual gas analyzer (QMS RGA) sensors, Fourier Transform Infrared (FTIR) sensors, chemiluminescence sensors, or any other sensors suitable for detecting hydrogen. In step 704, virgin hydrogen of a known purity is added to the recovered hydrogen so that the combined recovered hydrogen and virgin hydrogen meets a minimum predetermined composition/purity. By virgin hydrogen is meant hydrogen which has not been recovered from the silicon deposition process. A microcomputer, microprocessor, process logic controller, logic circuit, a combination of hardware and software, or the like may be used to determine the amount of virgin hydrogen which needs to be added to the recovered hydrogen in order to bring the combined hydrogen to the predetermined minimum specification.

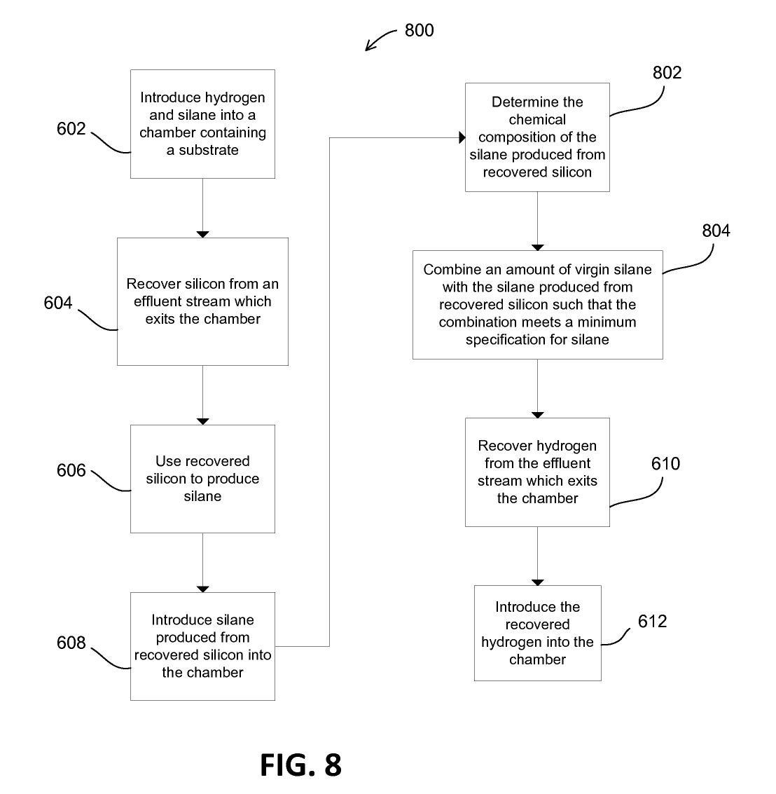

FIG. 8 is a flow chart depicting another method 800 of the invention for forming a silicon layer on a substrate. Method 800 may be similar to method 600, with the addition of the following steps. In step 802, the chemical composition of the silane produced from the recovered silicon is tested for composition and/or purity. Any suitable sensor may be used to determine the composition and/or purity of the recovered silane, including a quadrupole mass spectrometer residual gas analyzer (QMS RGA) sensors, Fourier Transform Infrared (FTIR) sensors, chemiluminescence sensors, or any other sensors suitable for detecting silane. In step 804, virgin silane of a known purity is added to the silane produced from the recovered silicon, as described above, so that the combined silane produced from the recovered silicon and virgin silane meets a minimum predetermined composition/purity. By virgin silane is meant silane which has not been produced from the recovered silane. A microcomputer, microprocessor, process logic controller, logic circuit, a combination of hardware and software, or the like may be used to determine the amount of virgin silane which needs to be added to the silane produced from the recovered silicon in order to bring the combined hydrogen to the predetermined minimum specification.

Some of the foregoing and other embodiments may include using waste heat from the abatement and or substrate coating process to drive refrigerated chillers or for cogeneration; recycling waste hydrogen, and or waste heat, and or waste SiO₂ to an on-site glass manufacturing plant for process use; using waste residual F₂ to etch substrate in the substrate factory to improve adhesion and remove trace metals from the surface via metal halide vaporization at high temperatures; using the blower and first stages on the conventional pump stack to boost the reclaim stream pre-inert (e.g., nitrogen) dilution, which would save capital cost of recycle blowers; and the entire system can be integrated as an optimal system rather than operated as individual components. In gigawatt solar plants, silane, hydrogen and nitrogen may be kept as liquids, not gases. Coolant streams which themselves need to be re-chilled may be passed through heat exchangers in the liquid silane, hydrogen and nitrogen tanks to cause those compounds to boil off for use, and to re-chill the coolant. In addition the abatement system compressors and pumps create heat which can be used to run chillers or create steam and/or electricity.

The present invention may be combined with processes whereby effluent may be taken from the post blower-pump package, after inert gas has been added, and hydrogen and silane then separated from the effluent.

The foregoing description discloses only exemplary embodiments of the invention. Modifications of the above disclosed apparatus and methods which fall within the scope of the invention will be readily apparent to those of ordinary skill in the art. For example, in the systems 300 and 400, the unused reagent gas may pass through a vacuum line and three-way valve as the unused reagent gases do in system 100A. Such modified systems may have control systems which divert effluent from the process chamber to either be recycled or abated depending upon whether the process chamber is in a deposition or in a chamber clean mode.

Following separation from impurities, and/or separation of silane from hydrogen, the reclaimed hydrogen and silane, or mixture of hydrogen and silane may then be sent to one or more of 1) separate feed tanks on gas pads (e.g., pads where reagent gases are stored); and 2) a gas box (e.g., mixing box) where the reclaimed gases may be mixed in real time with new feed stocks. In those embodiments where silane is separated from hydrogen, silane may be recompressed to a liquid for storage and blending back to the substrate coating process chamber.

If silane has been recompressed to a liquid and stored, the tank's internal gas regenerator heat exchanger may be used to thermally separate silane from heavier di- and tri-silane. The di- and tri-silane would become a tank bottom. Lower vapor pressure impurities may be removed from the tank bottom and the di- and tri-silane may be recycled to a silane plant as feedstock.

Finally, new silane and hydrogen may be added to the reclaimed mixture and the reclaim may be added to a buffer volume (e.g., a volume of gas which may be used to damp difference between the inflow and the outflow of the electronic device manufacturing process.)

Mass flow controllers and/or mass flow meters and throttle valves may be used by the process controller to control the composition and flow of gases into the process chamber and/or the flow of gases out of the process chamber, and the pressures of the gases in different locations of the system.

Accordingly, while the present invention has been disclosed in connection with exemplary embodiments thereof, it should be understood that other embodiments may fall within the spirit and scope of the invention, as defined by the following claims.

The invention claimed is:

1. A method of forming a silicon layer on a substrate comprising:
providing a substrate; and
introducing hydrogen and silane into a chamber containing the substrate such that a layer of silicon is deposited on the substrate;
wherein the silane is less than about 99.999% pure.

2. The method of claim 1 wherein the silane is less than about 99.99% pure.

3. The method of claim 1 wherein the silane is less than about 99.9% pure.

4. The method of claim 1 wherein the silane is less than about 99% pure.

5. The method of claim 1 wherein the silane is less than about 98% pure.

6. The method of claim 1 wherein the silane is less than about 95% pure.

7. The method of claim 1 wherein the substrate is an insulator.

8. The method of claim 1 wherein the silicon layer comprises amorphous silicon.

9. The method of claim 1 wherein the silicon layer comprises microcrystalline silicon.

10. The method of claim 1 wherein the silicon layer comprises a single crystal.

11. A method for forming a silicon layer on a substrate, comprising:
a) introducing hydrogen and silane into a deposition chamber containing a substrate such that a layer of silicon is deposited on the substrate;
b) recovering silicon from an effluent stream which exits the deposition chamber;
c) using the silicon recovered in step b) to produce silane;
d) using the silane produced in step c) as at least a part of the silane which is introduced into the deposition chamber in step a).

12. The method of claim 11 further comprising the steps:
e) determining a purity of the silane produced from the recovered silicon in step c); and
f) determining an amount of virgin silane which must be mixed with the silane produced from the recovered silicon to bring the resulting mixture up to a predetermined specification;
wherein step d) further comprises mixing the amount of virgin silane determined in step f) with the silane produced in step c).

13. The method of claim 11 further comprising:
e) recovering hydrogen from the effluent stream which exits the deposition chamber; and
f) using the hydrogen recovered in step e) as at least a part of the hydrogen which is introduced into the deposition chamber in step a).

14. The method of claim 13 further comprising the steps:
g) determining a purity of the hydrogen recovered from the effluent stream which exits the deposition chamber in step e); and
h) determining an amount of virgin hydrogen which must be mixed with the recovered hydrogen to bring the resulting mixture up to a predetermined specification;
wherein step f) further comprises mixing the amount of virgin hydrogen determined in step h) with the hydrogen recovered in step e).

15. A method for forming a silicon layer on a substrate, comprising:
a) introducing hydrogen and silane into a deposition chamber containing a substrate such that a layer of silicon is deposited on the substrate;
b) recovering silane from an effluent stream which exits the deposition chamber; and
c) introducing the silane recovered in step b), plus an amount of make-up silane sufficient to raise the purity of the combined recovered silane and make-up silane to at least a predetermined specification, to the deposition chamber.

16. The method of claim 15 further comprising:
d) recovering hydrogen from the effluent stream which exits the deposition chamber; and
f) introducing the hydrogen recovered in step d), plus an amount of make-up hydrogen sufficient to raise the purity of the combined recovered hydrogen and make-up hydrogen to at least a predetermined specification, to the deposition chamber.

17. An apparatus for depositing silicon on a substrate comprising:
a deposition chamber;
a source of silicon connected to the chamber;
a source of hydrogen connected to the chamber; and
a silicon separator adapted to receive an effluent stream produced by the deposition chamber and to provide silicon species suitable for use in producing silane.

18. The apparatus of claim 17, further comprising:
a hydrogen separator adapted to receive the effluent stream produced by the deposition chamber and to produce a recycled hydrogen stream; and
a gas box which is adapted to receive the recycled hydrogen stream from the hydrogen separator and to provide recycled hydrogen to the deposition chamber.

19. The apparatus of claim 18, wherein the gas box is further adapted to receive a first stream of silane produced from the silicon species separated from effluent stream, and to provide the first stream of silane to the deposition chamber.

20. The apparatus of claim 18, further comprising a gas composition sensor which is adapted to determine a purity of the recycled hydrogen stream which is received by the gas box.

21. The apparatus of claim 19, further comprising a gas composition sensor which is adapted to determine a purity of the silane stream which is received by the gas box.

22. The apparatus of claim 20, wherein the gas box is further adapted to receive a virgin stream of hydrogen, and further comprising a controller which is adapted to receive a signal from the gas composition sensor, wherein the controller is further adapted to instruct the gas box to mix virgin hydrogen with recycled hydrogen so that the hydrogen provided by the gas box to the deposition chamber meets a predetermined purity.

23. An apparatus for depositing silicon on a substrate comprising:
a deposition chamber;
a source of silicon connected to the chamber;
a source of hydrogen connected to the chamber;
a hydrogen separator adapted to receive an effluent stream produced by the deposition chamber and to produce a recycled hydrogen stream; and
a gas box which is adapted to receive the recycled hydrogen stream from the hydrogen separator and to provide recycled hydrogen to the deposition chamber.
